(19) United States
(12) Patent Application Publication
(10) Pub. No.: US 2025/0017011 A1
(43) Pub. Date: Jan. 9, 2025

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventor: Sung Wook JUNG, Icheon-si Gyeonggi-do (KR)

(73) Assignee: SK hynix Inc., Icheon-si Gyeonggi-do (KR)

(21) Appl. No.: 18/540,586

(22) Filed: Dec. 14, 2023

(30) Foreign Application Priority Data
Jul. 3, 2023 (KR) 10-2023-0085853

(51) Int. Cl. H10B 43/27; H01L 29/792

(52) U.S. Cl. CPC H10B 43/27; H01L 29/7926

(57) ABSTRACT

There are provided a semiconductor device and a manufacturing method of a semiconductor device. The semiconductor device includes: a gate stack structure including interlayer insulating layers and conductive layers, which are alternately stacked; a channel structure extending in a vertical direction in the gate stack structure; and memory structures interposed between the conductive layers and the channel structure. Each of the memory structures includes a blocking insulating layer and a charge trap layer, which are sequentially formed on a sidewall of each of the conductive layers. Sidewalls of the interlayer insulating layers, which are in contact with the channel structure, are located on the same line as a sidewall of the charge trap layer, which is in contact with the channel structure, or side portions of the interlayer insulating layers, which are in contact with the channel structure, further protrude as compared with the sidewall of the charge trap layer.

### CROSS-REFERENCE TO RELATED APPLICATION

The present application claims priority under 35 U.S.C. § 119(a) to Korean patent application number 10-2023-0085853 filed on Jul. 3, 2023, in the Korean Intellectual Property Office, the entire disclosure of which is incorporated by reference herein.

### BACKGROUND

### 1. Technical Field

The present disclosure generally relates to an electronic device, and more particularly, to a semiconductor device and a manufacturing method of a semiconductor device.

### 2. Related Art

A nonvolatile memory device is a memory device in which stored data is retained as it is even when power supply is interrupted. As the improvement of the degree of integration of two-dimensional nonvolatile memory devices in which memory cells are formed in the form of a single layer over a substrate reaches the limit, there has recently been proposed a three-dimensional nonvolatile memory device in which memory cells are stacked vertically over a substrate.

The three-dimensional nonvolatile memory device includes interlayer insulating layers and gate electrodes, which are alternately stacked, and channel layers penetrating the interlayer insulating layers and the gate electrodes, and memory cells are stacked along the channel layers. Various structures and various manufacturing methods have been developed to improve the operational reliability of such a nonvolatile memory device having a three-dimensional structure.

### SUMMARY

In accordance with an embodiment of the present disclosure, there is provided a semiconductor device including: a gate stack structure including interlayer insulating layers and conductive layers, which are alternately stacked; a channel structure extending in a vertical direction in the gate stack structure; and memory structures interposed between the conductive layers and the channel structure, wherein each of the memory structures includes a blocking insulating layer and a charge trap layer, which are sequentially formed on a sidewall of each of the conductive layers, and wherein sidewalls of the interlayer insulating layers, which are in contact with the channel structure, are located on the same line as a sidewall of the charge trap layer, which is in contact with the channel structure, or side portions of the interlayer insulating layers, which are in contact with the channel structure, further protrude toward the channel layer as compared with the sidewall of the charge trap layer.

In accordance with an embodiment of the present disclosure, there is provided a method of manufacturing a semiconductor device, the method including: forming a vertical hole at least a portion of a stack structure in which first material layers and the second material layers are alternately stacked; forming recess regions by etching, to a certain thickness, sidewalls of the second material layers, which are exposed through the vertical hole; forming blocking insulating layers by oxidizing the sidewalls of the second material layers, which are exposed through the recess regions; forming charge trap layers in the respective recess regions, wherein the charge trap layers are spaced apart from each other in a vertical direction by the first material layers; and sequentially forming a tunnel insulating layer and a channel layer along a sidewall of the vertical hole.

In accordance with an embodiment of the present disclosure, there is provided a semiconductor device including: a gate stack structure including interlayer insulating layers and conductive layers, which are alternately stacked; a channel layer extending in a vertical direction in the gate stack structure; and memory structures interposed between the conductive layers and the channel structure, wherein each of the memory structures includes a blocking insulating layer, a charge trap layer, and a tunnel insulating layer, which are sequentially formed on a sidewall of each of the conductive layers, and wherein sidewalls of the interlayer insulating layers, which are in contact with the channel structure, are located on the same line as a sidewall of the tunnel insulating layer, which is in contact with the channel structure, or side portions of the interlayer insulating layers, which are in contact with the channel structure, further protrude toward the channel structure as compared with the sidewall of the tunnel insulating layer.

In accordance with an embodiment of the present disclosure, there is provided a method of manufacturing a semiconductor device, the method including: forming a vertical hole at least a portion of a stack structure in which first material layers and the second material layers are alternately stacked; forming first recess regions by etching, to a certain thickness, sidewalls of the second material layers, which are exposed through the vertical hole; forming blocking insulating layers by oxidizing the sidewalls of the second material layers, which are exposed through the first recess regions; forming charge trap layers in the respective first recess regions, wherein the charge trap layers are spaced apart from each other in a vertical direction by the first material layers; forming second recess regions by etching, to a certain thickness, sidewalls of the charge trap layers, which are exposed through the vertical hole; forming tunnel insulating layers in the respective second recess regions; and forming a channel layer along a sidewall of the vertical hole.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a semiconductor device in accordance with an embodiment of the present disclosure.

FIG. 2 is a sectional view illustrating a memory cell array of a semiconductor device in accordance with an embodiment of the present disclosure.

FIGS. 3A, 3B, 3C, 3D, 3E, 3F, and 3G are sectional views illustrating a manufacturing method of the semiconductor device in accordance with an embodiment of the present disclosure.

FIG. 4 is a sectional view illustrating a memory cell array of a semiconductor device in accordance with an embodiment of the present disclosure.

FIGS. 5A, 5B, 5C, 5D, 5E, 5F, 5G, and 5H are sectional views illustrating a manufacturing method of the semiconductor device in accordance with another embodiment of the present disclosure.

FIG. 6 is a block diagram illustrating a Solid State Drive (SSD) system to which the semiconductor device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Embodiments provide a semiconductor device and a manufacturing method of a semiconductor device, in which charge trap layers of a plurality of memory cells stacked in a vertical direction are electrically and physically spaced apart from each other.

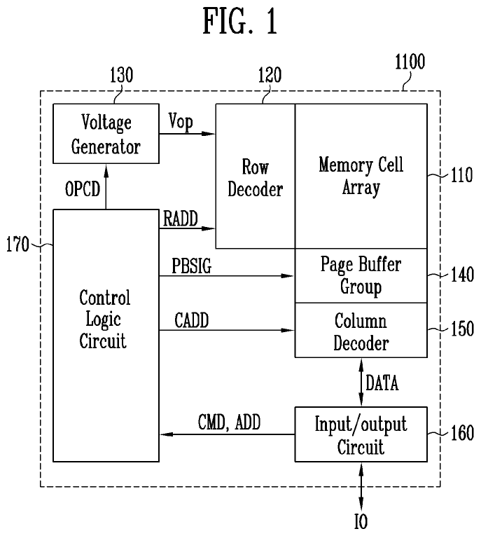

FIG. 1 is a diagram illustrating a semiconductor device in accordance with an embodiment of the present disclosure.

Referring to FIG. 1, the semiconductor device 1100 may include a memory cell array 110 in which data is stored and a peripheral circuit 120 to 170 capable of performing a program, read or erase operation.

The memory cell array 110 may include a plurality of memory blocks in which data is stored. Each of the memory blocks may include a plurality of memory cells, and the plurality of memory cells may be nonvolatile memory cells. The nonvolatile memory cells may be implemented in a three-dimensional structure in which the nonvolatile memory cells are stacked in a vertical direction above a substrate.

The peripheral circuit 120 to 170 may include a row decoder 120, a voltage generator 130, a page buffer group 140, a column decoder 150, an input/output circuit 160, and a control logic circuit 170.

The row decoder 120 may select one memory block among the memory blocks included in the memory cell array 110 according to a row address RADD, and transmit operating voltages Vop to the selected memory block.

The voltage generator 130 may generate and output operating voltages Vop necessary for various operations in response to an operation code OPCD. For example, in response to the operation code OPCD, the voltage generator 130 may generate a set voltage, a reset voltage, a turn-on voltage, a turn-off voltage, a read voltage, an erase voltage, and the like, and selectively output the generated voltages. In accordance with this embodiment, the voltage generator 130 may generate voltages of OV or higher as voltages to be applied to word lines, and include a device which generates a negative voltage lower than OV.

The page buffer group 140 may be connected to the memory cell array 110 through bit lines. For example, the page buffer group 140 may include page buffers connected to the respective bit lines. The page buffers may simultaneously operate in response to page buffer control signals PBSIG, and store data in a program or read operation. The page buffers may sense a current of the bit lines, which varies according to a threshold voltage of the memory cells, in a read or verify operation. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The column decoder 150 may transmit data DATA between the input/output circuit 160 and the page buffer group 140 according to a column address CADD.

The input/output circuit 160 may be connected to an external device through input/output lines IO. For example, the external device may be a controller capable of transmitting a command CMD, an address ADD, or data DATA to the memory device 1100. The input/output circuit 160 may input/output a command CMD, an address ADD, and data DATA through the input/output lines IO. For example, the input/output circuit 160 may transmit the command CMD and the address ADD, which are received from the external device, to the control logic circuit 170 through the input/output lines IO, and transmit the data DATA received from the external device to the column decoder 150 through the input/output lines IO. The input/output circuit 160 may output the data DATA received from the column decoder 150 to the external device through the input/output lines IO.

The control logic circuit 170 outputs the operation code OPCD, the row address RADD, the page buffer control signals PBSIG, and the column address CADD in response to the command CMD and the address ADD. For example, the control logic circuit 170 may include software configured to perform an algorithm in response to the command CMD and hardware configured to output the address ADD and various control signals.

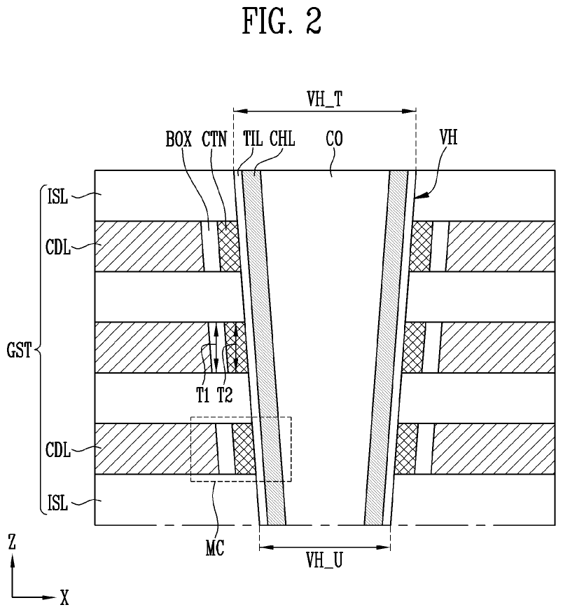

FIG. 2 is a sectional view illustrating a memory cell array of a semiconductor device in accordance with an embodiment of the present disclosure.

The memory cell array 110 shown in FIG. 1 may include memory blocks including a plurality of nonvolatile memory cells, and a portion of a string included in a memory block is illustrated in FIG. 2.

Referring to FIG. 2, the string may include a plurality of nonvolatile memory cells MC, and the plurality of nonvolatile memory cells MC may be connected to conductive layers CDL corresponding to word lines. Each of the plurality of non-volatile memory cells MC may be configured to include a conductive layer CDL, a blocking insulating layer BOX, a charge trap layer CTN, a tunnel insulating layer TIL, and a channel layer CHL.

Interlayer insulating layers ISL may be formed between the conductive layers CDL. The conductive layers CDL and the interlayer insulating layers ISL may extend in an X direction as a direction horizontal to a substrate. A gate stack structure GST may be formed including the conductive layers CDL and the interlayer insulating layers ISL. For example, the interlayer insulating layers ISL and the conductive layers CDL may be alternately stacked on the top of a lower structure (not shown). The lower structure may include at least one of a substrate or a source line formed on the substrate, a source select line, and peripheral circuits. Each of the conductive layers CDL may be used as a word line or a select line. For example, when the interlayer insulating layers ISL and the conductive layers CDL are alternately stacked on the substrate, the conductive layers CDL may include word lines and select lines. The interlayer insulating layers ISL may be formed of oxide, and the conductive layers CDL may be formed of a metal such as tungsten.

A vertical hole VH penetrating the interlayer insulating layers ISL and the conductive layers CDL in a Z direction as a direction vertical to the substrate may be formed in the string. The vertical hole VH may have a width which becomes narrower as approaching a bottom end thereof. For example, a width VH_U of the bottom end of the vertical hole VH may be narrower than a width VH_T of a top end of the vertical hole VH.

The interlayer insulating layers ISL may further protrude in a direction adjacent to the vertical hole VH as compared with the conductive layers CDL. That is, the blocking insulating layer BOX and the charge trap layer CTN may be interposed in a space between protrusion parts of interlayer insulating layers adjacent to each other in the Z direction as the direction vertical to the substrate. That is, the blocking insulating layer BOX and the charge trap layer CTN may be interposed between the conductive layers CDL and the vertical hole VH. In an embodiment of the present disclosure, the blocking insulating layer BOX and the charge trap layer CTN may be defined as a memory structure.

The tunnel insulating layer TIL and the channel layer CHL may be sequentially formed along a sidewall of the vertical hole VH. For example, the tunnel insulating layer TIL may be formed along the sidewall of the vertical hole VH, i.e., sidewalls of the interlayer insulating layers ISL and the charge trap layer CTN, and the channel layer CHL may be formed along a sidewall of the tunnel insulating layer TIL. A core insulating layer CO may be formed in a central region of the vertical hole VH. In an embodiment of the present disclosure, the tunnel insulating layer TIL, the channel layer CHL, and the core insulating layer CO may be defined as a vertical channel structure.

The tunnel insulating layer TIL may be a layer in which charges are tunneled by F-N tunneling or the like, and include an insulating material such as oxide or nitride. The charge trap layer CTN may include a plurality of trap sites, and charges introduced while passing through the tunnel insulating layer TIL may be trapped in the charge trap layer CTN in a program operation. The charge trap layer CTN may include nitride, a chalcogenide compound, or a metal oxide. In an embodiment, the blocking insulating layer BOX may prevent or mitigate charges trapped in the charge trap layer CTN from being moved to the conductive layers CDL, and include a high dielectric constant material such as aluminum oxide (Al₂O₃), hafnium oxide (HfOₓ), or hafnium silicon oxide (HfSiOₓ). The channel layer CHL may be used to allow a current to flow in the string, and be formed of poly-silicon.

The channel layer CHL may have a cylindrical structure extending in the Z direction as the vertical direction in the vertical hole VH. The tunnel insulating layer TIL may extend in the Z direction as the vertical direction in the vertical hole VH, and be formed to surround an outside wall of the channel layer CHL.

The charge trap layer CTN may be formed to surround a portion of an outside wall of the tunnel insulating layer TIL, and a charge trap layer CTN corresponding to one nonvolatile memory cell MC may have a structure isolated from a charge trap layer CTN corresponding to another nonvolatile memory cell MC adjacent to the one nonvolatile memory cell MC in the Z direction as the vertical direction by one interlayer insulating layer ISL. Accordingly, in an embodiment, interference and disturb phenomena between nonvolatile memory cells MC adjacent to each other in the Z direction can be reduced.

In addition, the blocking insulating layer BOX may be formed to surround an outside wall of the charge trap layer CTN, and a blocking insulating layer BOX corresponding to one nonvolatile memory cell MC may have a structure isolated from a blocking insulating layer BOX corresponding to another nonvolatile memory cell MC adjacent to the one nonvolatile memory cell MC in the Z direction as the vertical direction by one interlayer insulating layer ISL.

A vertical thickness T1 of a blocking insulating layer BOX corresponding to one nonvolatile memory cell MC and a vertical thickness T2 of a charge trap layer CTN corresponding to the one nonvolatile memory cell MC may be the same. A sidewall of the interlayer insulating layer ISL, which is in contact with the vertical hole VH, may be located on the same line as a sidewall of the charge trap layer CTN, which is in contact with the vertical hole VH, or a side portion of the interlayer insulating layer ISL, which is in contact with the vertical hole VH, may be formed to further protrude as compared with the sidewall of the charge trap layer CTN, which is in contact with the vertical hole VH. In addition, upper surface heights of a conductive layer CDL, a blocking insulating layer BOX, and a charge trap layer CTN, which correspond to one nonvolatile memory cell MC, may be the same. In addition, lower surface heights of a conductive layer CDL, a blocking insulating layer BOX, and a charge trap layer CTN, which correspond to one nonvolatile memory cell MC, may be the same.

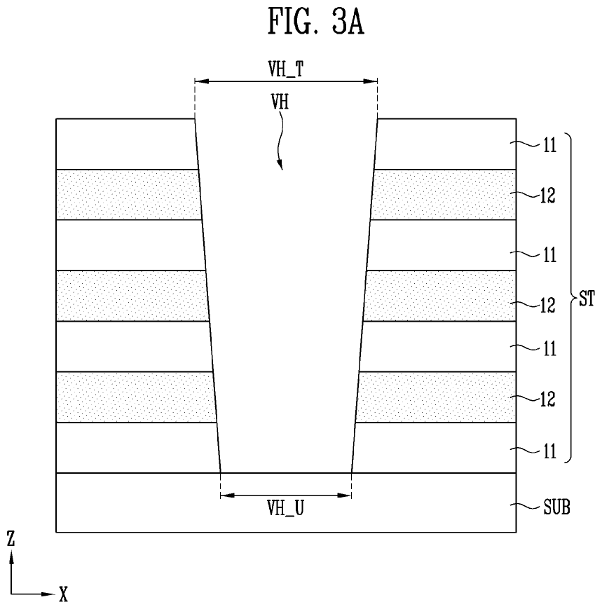

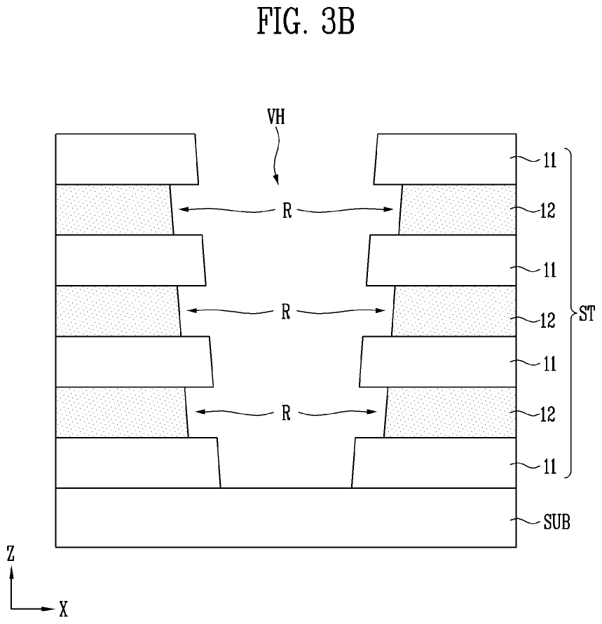

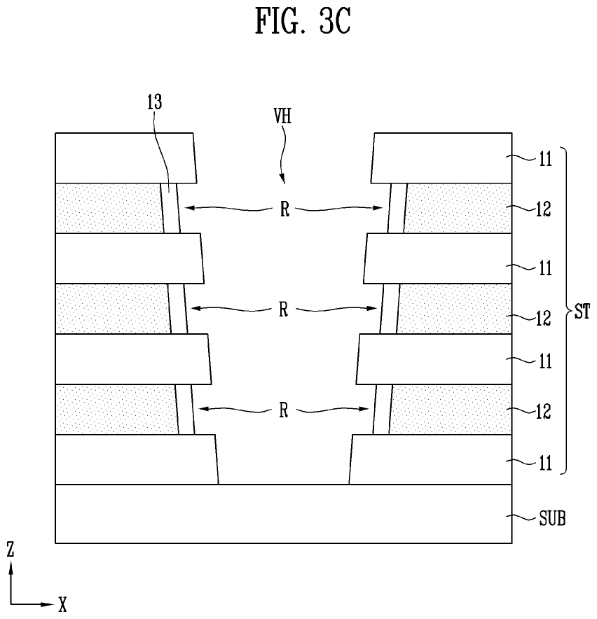

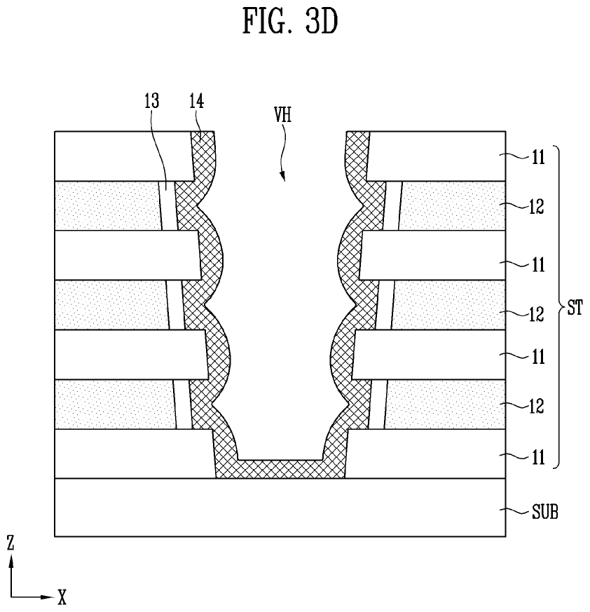

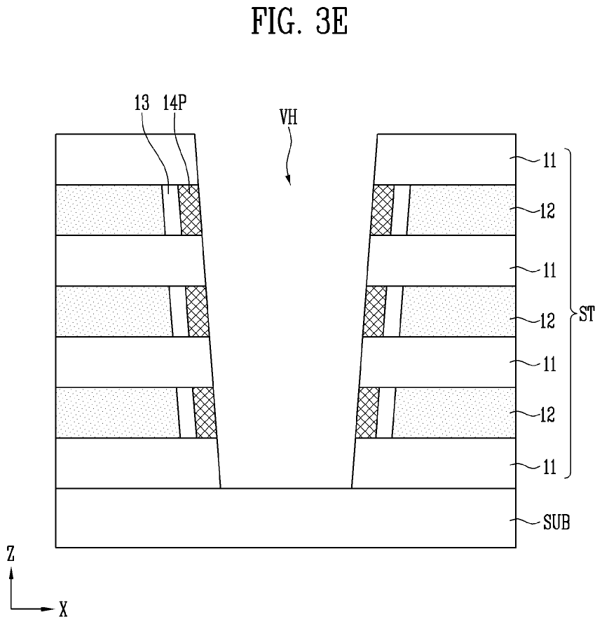

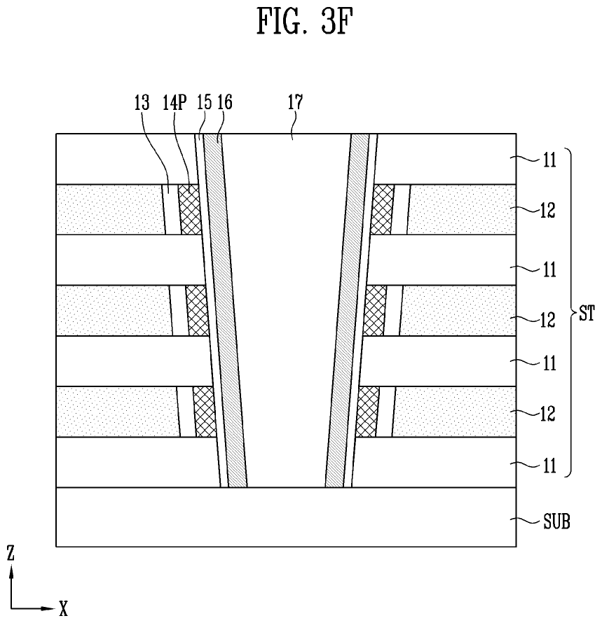

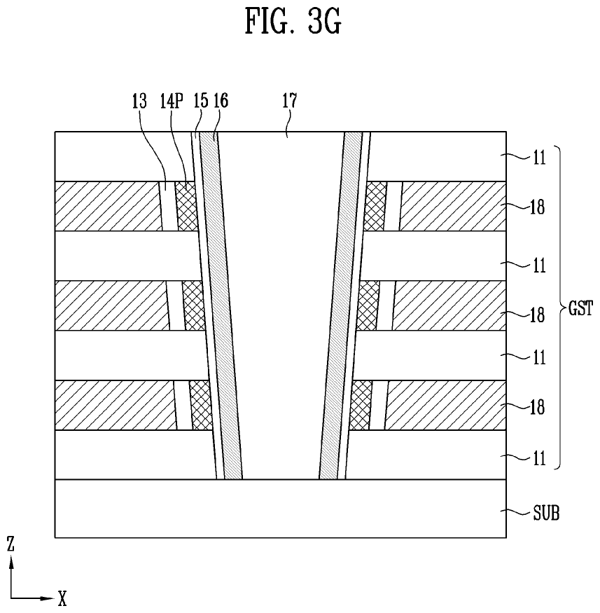

FIGS. 3A to 3G are sectional views illustrating a manufacturing method of the semiconductor device in accordance with an embodiment of the present disclosure.

Referring to FIG. 3A, a stack structure ST may be formed on a substrate SUB. The stack structure ST may include first material layers 11 and second material layers 12, which are alternately stacked. The first and second material layers 11 and 12 may extend in an X direction as a direction horizontal to the substrate SUB. The first and second material layers 11 and 12 may be stacked in a Z direction as a direction vertical to the substrate SUB. The first and second material layers 11 and 12 may be formed using a deposition process such as Chemical Vapor Deposition (CVD).

The first material layers 11 may include a material having a high etch selectivity with respect to the second material layers 12. In an example, the first material layers 11 may include an insulating material such as oxide, and the second material layers 12 may include a sacrificial material such as nitride. In another example, the first material layers 11 may include an insulating material such as oxide, and the second material layers 12 may include a conductive material such as poly-silicon, tungsten, molybdenum or metal.

Subsequently, a vertical hole VH penetrating the stack structure ST may be formed. The vertical hole VH may have a cylindrical shape extending in the Z direction. The vertical hole VH may be formed such that a width VH_T of a top end thereof is wider than a width VH_U of a bottom end thereof.

Referring to FIG. 3B, sidewalls of the second material layers 12, which are exposed through the vertical hole VH, may be etched to a certain depth, thereby forming recess regions R. That is, the sidewalls of the second material layers 12 may be etched to a certain depth such that the first material layers 11 protrude in the horizontal direction as compared with the second material layers 12. Therefore, a sidewall of the vertical hole VH may be formed in a structure in which uneven portions are sequentially disposed in the Z direction as the direction vertical to the substrate SUB.

Referring to FIG. 3C, the sidewall of each of the second material layers 12, which is exposed through the vertical hole VH, may be oxidized through an oxidation process, thereby forming a blocking insulating layer 13. The oxidation process may be performed as a radical oxidation process or a wet oxidation process. The sidewall of each of the second material layers 12 may be oxidized to a certain thickness through the oxidation process, to form the blocking insulating layer 13.

Referring to FIG. 3D, a charge trap source layer 14 may be formed along the sidewall of the vertical hole VH. The charge trap source layer 14 may be formed by adjusting a thickness thereof such that the recess regions R shown in FIG. 3C are completely buried. The charge trap source layer 14 may include a charge trap material, nitride, a variable resistance material or nano structure, a chalcogenide compound or a metal oxide, or include any combination thereof.

Referring to FIG. 3E, an etching process may be performed such that the charge trap source layer (14 shown in FIG. 3D) remains in only each of the recess regions (R shown in FIG. 3C), thereby forming a charge trap layer 14P. That is, the charge trap source layer (14 shown in FIG. 3D) formed on sidewalls of the first material layers 11 may be etched and removed, thereby physically and electrically isolating the charge trap layers 14 formed in the recess regions (R shown in FIG. 3C) from each other in the Z direction. That is, charge trap layers 14P adjacent to each other in the Z direction may have a structure in which the charge trap layers 14P are spaced apart from each other by one first material layer 11.

Referring to FIG. 3F, a tunnel insulating layer 15 and a channel layer 16 may be sequentially formed along the sidewall of the vertical hole (VH shown in FIG. 3E). The tunnel insulating layer 15 may be a layer in which charges are tunneled by F-N tunneling or the like, and include an insulating material such as oxide or nitride. The channel layer 16 may include poly-silicon.

The tunnel insulating layer 15 may be formed along the sidewalls of the first material layers 11 and sidewalls of the charge trap layers 14P. The tunnel insulating layer 15 and the channel layer 16 may be formed to extend in the Z direction.

After that, a core insulating layer 17 may be formed such that a central region of the vertical hole (VH shown in FIG. 3E) is filled therewith. The core insulating layer 17 may include oxide. When the central region of the vertical hole (VH shown in FIG. 3E) is filled by the channel layer 16, a process of forming the core insulating layer 17 may be skipped.

Referring to FIG. 3G, the second material layers (12 shown in FIG. 3F) may be replaced with conductive layers 18. For example, a slit extending in the X direction may be formed through etching of the stack structure (ST shown in FIG. 3F), thereby exposing sidewalls of the second material layers (12 shown in FIG. 3F). After that, the second material layers (12 shown in FIG. 3F) exposed through the slit may be selectively etched and removed, and spaces in which the second material layers (12 shown in FIG. 3F) are removed may be filled with a conductive material, thereby forming the conductive layers 18.

The first material layers 11 and the conductive layers 18 may be defined as a gate stack structure GST.

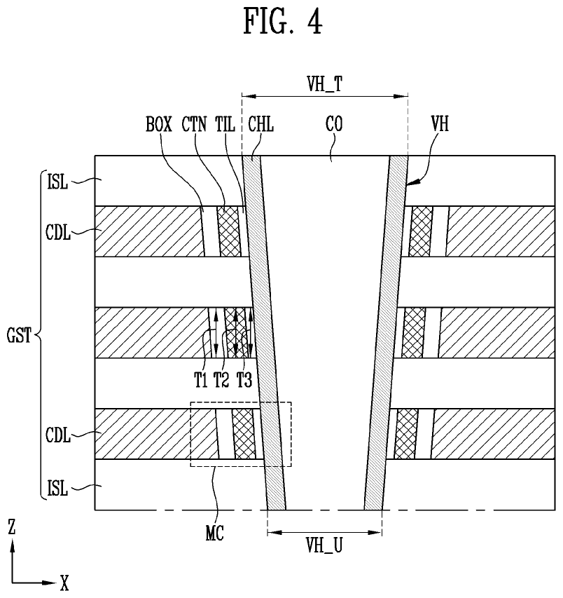

FIG. 4 is a sectional view illustrating a memory cell array of a semiconductor device in accordance with an embodiment of the present disclosure.

The memory cell array 110 shown in FIG. 1 may include memory blocks including a plurality of nonvolatile memory cells, and a portion of a string included in a memory block is illustrated in FIG. 4.

Referring to FIG. 4, the string may include a plurality of nonvolatile memory cells MC, and the plurality of nonvolatile memory cells MC may be connected to conductive layers CDL corresponding to word lines. Each of the plurality of non-volatile memory cells MC may be configured to include a conductive layer CDL, a blocking insulating layer BOX, a charge trap layer CTN, a tunnel insulating layer TIL, and a channel layer CHL.

Interlayer insulating layers ISL may be formed between the conductive layers CDL. The conductive layers CDL and the interlayer insulating layers ISL may extend in an X direction as a direction horizontal to a substrate. A gate stack structure GST may be formed including the conductive layers CDL and the interlayer insulating layers ISL. For example, the interlayer insulating layers ISL and the conductive layers CDL may be alternately stacked on the top of a lower structure (not shown). The lower structure may include at least one of a substrate or a source line formed on the substrate, a source select line, and peripheral circuits. Each of the conductive layers CDL may be used as a word line or a select line. For example, when the interlayer insulating layers ISL and the conductive layers CDL are alternately stacked on the substrate, the conductive layers CDL may include word lines and select lines. The interlayer insulating layers ISL may be formed of oxide, and the conductive layers CDL may be formed of a metal such as tungsten.

A vertical hole VH penetrating the interlayer insulating layers ISL and the conductive layers CDL in a Z direction as a direction vertical to the substrate may be formed in the string. The vertical hole VH may have a width which becomes narrower as approaching a bottom end thereof. For example, a width VH_U of the bottom end of the vertical hole VH may be narrower than a width VH_T of a top end of the vertical hole VH.

The interlayer insulating layers ISL may further protrude in a direction adjacent to the vertical hole VH as compared with the conductive layers CDL. That is, the blocking insulating layer BOX and the charge trap layer CTN may be interposed in a space between protrusion parts of interlayer insulating layers adjacent to each other in the Z direction as the direction vertical to the substrate. That is, the blocking insulating layer BOX, the charge trap layer CTN, and the tunnel insulating layer TIL may be interposed between the conductive layers CDL and the vertical hole VH. In an embodiment of the present disclosure, the blocking insulating layer BOX, the charge trap layer CTN, and the tunnel insulating layer TIL may be defined as a memory structure.

The channel layer CHL may be sequentially formed along a sidewall of the vertical hole VH. For example, the channel layer CH may be formed along the sidewall of the vertical hole VH, i.e., sidewalls of the interlayer insulating layers ISL and the tunnel insulating layer TIL. A core insulating layer CO may be formed in a central region of the vertical hole VH. In an embodiment of the present disclosure, the channel layer CHL and the core insulating layer CO may be defined as a vertical channel structure.

The tunnel insulating layer TIL may be a layer in which charges are tunneled by F-N tunneling or the like, and include an insulating material such as oxide or nitride. The charge trap layer CTN may include a plurality of trap sites, and charges introduced while passing through the tunnel insulating layer TIL may be trapped in the charge trap layer CTN in a program operation. The charge trap layer CTN may include nitride, a chalcogenide compound, or a metal oxide. In an embodiment, the blocking insulating layer BOX may prevent or mitigate charges trapped in the charge trap layer CTN from being moved to the conductive layers CDL, and include a high dielectric constant material such as aluminum oxide (Al₂O₃), hafnium oxide (HfOₓ), or hafnium silicon oxide (HfSiOₓ). In an embodiment, the channel layer CHL may be used to allow a current to flow in the string, and be formed of poly-silicon.

The channel layer CHL may have a cylindrical structure extending in the Z direction as the vertical direction in the vertical hole VH.

The tunnel insulating layer TIL may be formed to surround a portion of an outside wall of the channel layer CHL, and a tunnel insulating layer TIL corresponding to one nonvolatile memory cell MC may have a structure isolated from a tunnel insulating layer TIL corresponding to another nonvolatile memory cell MC adjacent to the one nonvolatile memory cell MC in the Z direction as the vertical direction by one interlayer insulating layer ISL.

The charge trap layer CTN may be formed to surround an outside wall of the tunnel insulating layer TIL, and a charge trap layer CTN corresponding to one nonvolatile memory cell MC may have a structure isolated from a charge trap layer CTN corresponding to another nonvolatile memory cell MC adjacent to the one nonvolatile memory cell MC in the Z direction as the vertical direction by one interlayer insulating layer ISL. Accordingly, in an embodiment, interference and disturb phenomena between nonvolatile memory cells MC adjacent to each other in the Z direction can be reduced.

In addition, the blocking insulating layer BOX may be formed to surround an outside wall of the charge trap layer CTN, and a blocking insulating layer BOX corresponding to one nonvolatile memory cell MC may have a structure isolated from a blocking insulating layer BOX corresponding to another nonvolatile memory cell MC adjacent to the one nonvolatile memory cell MC in the Z direction as the vertical direction by one interlayer insulating layer ISL.

A vertical thickness T1 of a blocking insulating layer BOX corresponding to one nonvolatile memory cell MC, a vertical thickness T2 of a charge trap layer CTN corresponding to the one nonvolatile memory cell MC, and a vertical thickness T3 of a tunnel insulating layer TIL corresponding to the one nonvolatile memory cell MC may be the same. A sidewall of the interlayer insulating layer ISL, which is in contact with the vertical hole VH, may be located on the same line as a sidewall of the tunnel insulating layer TIL, which is in contact with the vertical hole VH, or a side portion of the interlayer insulating layer ISL, which is in contact with the vertical hole VH, may be formed to further protrude as compared with the sidewall of the tunnel insulating layer, which is in contact with the vertical hole VH. In addition, upper surface heights of a conductive layer CDL, a blocking insulating layer BOX, a charge trap layer CTN, and a tunnel insulating layer TIL, which correspond to one nonvolatile memory cell MC, may be the same. In addition, lower surface heights of a conductive layer CDL, a blocking insulating layer BOX, a charge trap layer CTN, and a tunnel insulating layer TIL, which correspond to one nonvolatile memory cell MC, may be the same.

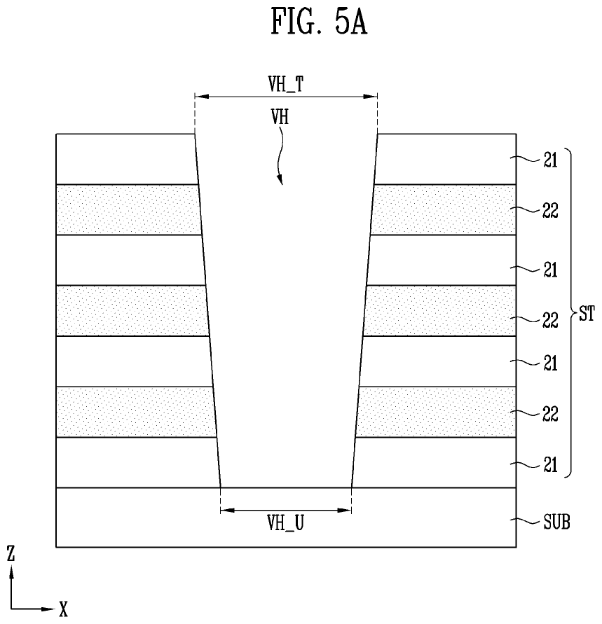

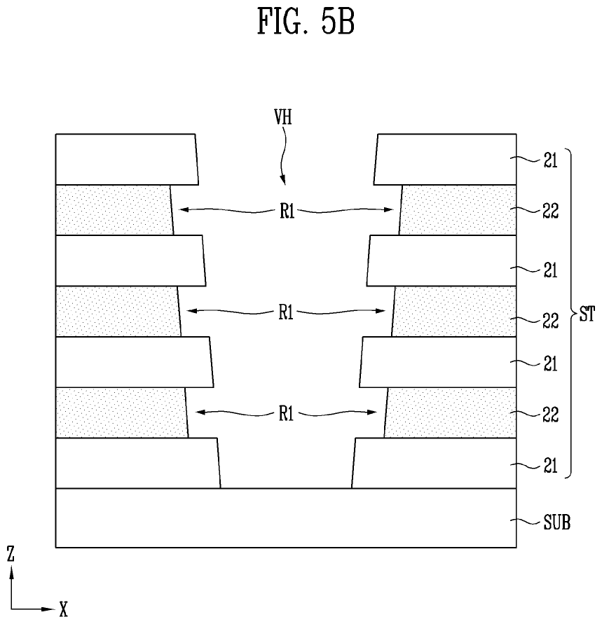

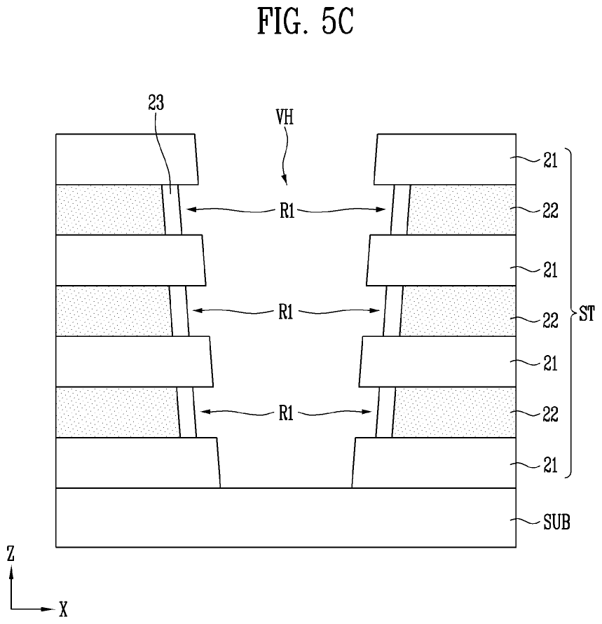

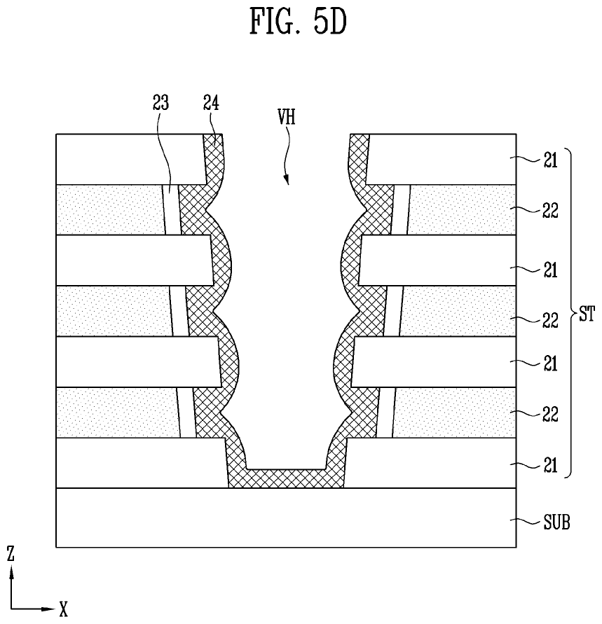

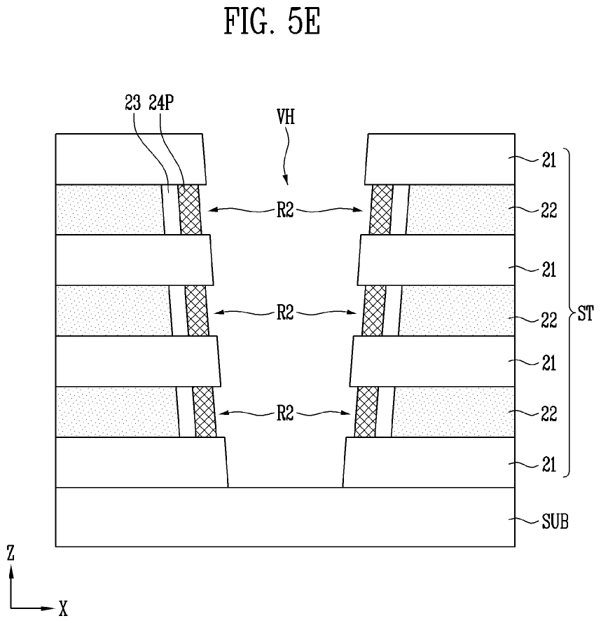

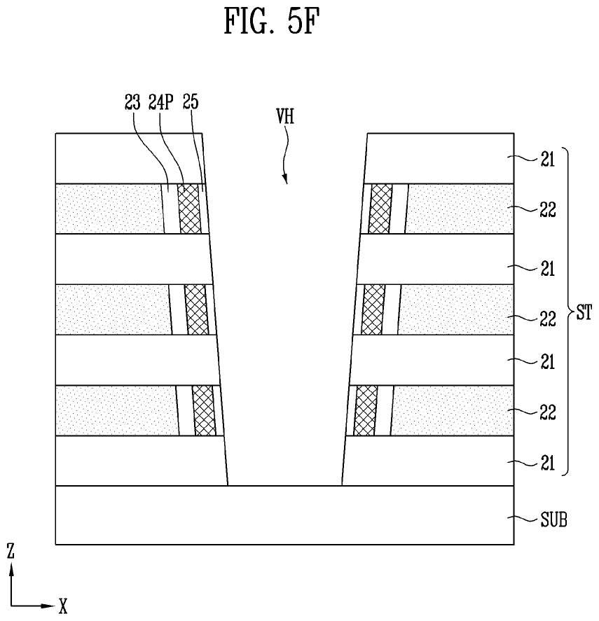

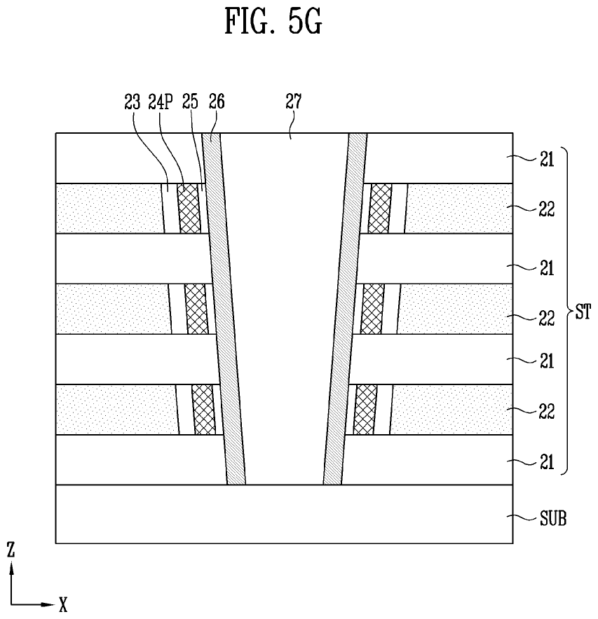

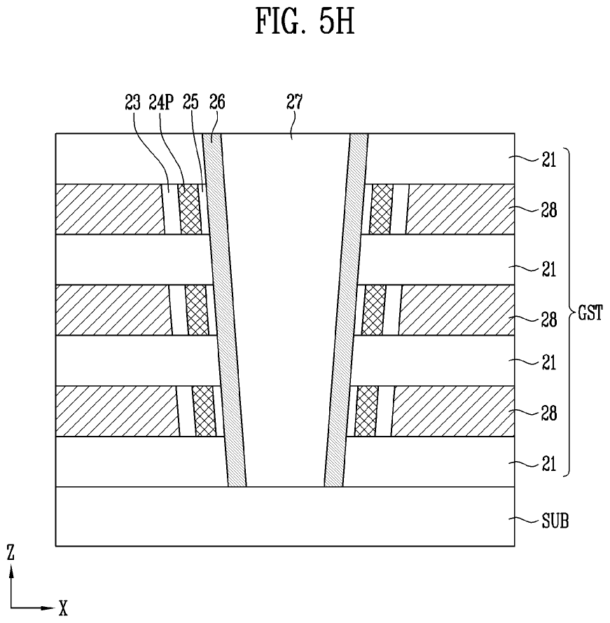

FIGS. 5A to 5H are sectional views illustrating a manufacturing method of the semiconductor device in accordance with an embodiment of the present disclosure.

Referring to FIG. 5A, a stack structure ST may be formed on a substrate SUB. The stack structure ST may include first material layers 21 and second material layers 22, which are alternately stacked. The first and second material layers 21 and 22 may extend in an X direction as a direction horizontal to the substrate SUB. The first and second material layers 21 and 22 may be stacked in a Z direction as a direction vertical to the substrate SUB. The first and second material layers 21 and 22 may be formed using a deposition process such as Chemical Vapor Deposition (CVD).

The first material layers 21 may include a material having a high etch selectivity with respect to the second material layers 22. In an example, the first material layers 21 may include an insulating material such as oxide, and the second material layers 22 may include a sacrificial material such as nitride. In another example, the first material layers 21 may include an insulating material such as oxide, and the second material layers 22 may include a conductive material such as poly-silicon, tungsten, molybdenum or metal.

Subsequently, a vertical hole VH penetrating the stack structure ST may be formed. The vertical hole VH may have a cylindrical shape extending in the Z direction. The vertical hole VH may be formed such that a width VH_T of a top end thereof is wider than a width VH_U of a bottom end thereof.

Referring to FIG. 5B, sidewalls of the second material layers 22, which are exposed through the vertical hole VH, may be etched to a certain depth, thereby forming first recess regions R1. That is, the sidewalls of the second material layers 22 may be etched to a certain depth such that the first material layers 21 protrude in the horizontal direction as compared with the second material layers 22. Therefore, a sidewall of the vertical hole VH may be formed in a structure in which uneven portions are sequentially disposed in the Z direction as the direction vertical to the substrate SUB.

Referring to FIG. 5C, the sidewall of each of the second material layers 22, which are exposed through the vertical hole VH, may be oxidized through an oxidation process, thereby forming a blocking insulating layer 23. The oxidation process may be performed as a radical oxidation process or a wet oxidation process. The sidewall of each of the second material layers 22 may be oxidized to a certain thickness through the oxidation process, to form the blocking insulating layer 23.

Referring to FIG. 5D, a charge trap source layer 24 may be layer 24 may be formed by adjusting a thickness thereof such that the first recess regions R1 shown in FIG. 5C are buried. The charge trap source layer 24 may be formed such that the first recess regions R1 are completely buried or are partially buried.

The charge trap source layer 24 may include a charge trap material, nitride, a variable resistance material or nano structure, a chalcogenide compound or a metal oxide, or include any combination thereof.

Referring to FIG. 5E, an etching process may be performed such that the charge trap source layer (24 shown in FIG. 5D) remains in only each of the first recess regions (R1 shown in FIG. 5C), thereby forming a charge trap layer 24P. That is, the charge trap source layer (24 shown in FIG. 5D) formed on sidewalls of the first material layers 21 may be etched and removed, thereby physically and electrically isolating the charge trap layers 24 formed in the first recess regions (R1 shown in FIG. 5C) from each other in the Z direction. That is, charge trap layers 24P adjacent to each other in the Z direction may have a structure in which the charge trap layers 24P are spaced apart from each other by one first material layer 21.

After that, the charge trap layers 24P exposed through the vertical hole VH may be etched to a certain thickness through an additional etching process, thereby forming second recess regions R2. That is, sidewalls of the charge trap layers 24P may be etched to a certain depth such that the first material layers 21 protrude in the horizontal direction as compared with the charge trap layers 24P.

Referring to FIG. 5F, a tunnel insulating layer 25 may be formed in each of the second recess regions (R2 shown in FIG. 5E). The tunnel insulating layer 25 may be formed to be in contact with the sidewall of each of the charge trap layers 24P through an oxidation process. The tunnel insulating layer 25 may be a layer in which charges are tunneled by F-N tunneling or the like, and include an insulating material such as oxide or nitride.

Referring to FIG. 5G, a channel layer 26 may be formed along the sidewall of the vertical hole (VH shown in FIG. 5F). The channel layer 26 may include poly-silicon.

The channel layer 26 may be formed the sidewalls of the first material layers 21 and sidewalls of the tunnel insulating layers 25. The channel layer 26 may be formed to extend in the Z direction.

After that, a core insulating layer 27 may be formed such that a central region of the vertical hole (VH shown in FIG. 5F) is filled therewith. The core insulating layer 27 may include oxide. When the central region of the vertical hole (VH shown in FIG. 5F) is filled by the channel layer 26, a process of forming the core insulating layer 27 may be skipped.

Referring to FIG. 5H, the second material layers (22 shown in FIG. 5G) may be replaced with conductive layers 28. For example, a slit extending in the X direction may be formed through etching of the stack structure (ST shown in FIG. 5G), thereby exposing sidewalls of the second material layers (22 shown in FIG. 5G). After that, the second material layers (22 shown in FIG. 5G) exposed through the slit may be selectively etched and removed, and spaces in which the second material layers (22 shown in FIG. 5G) are removed may be filled with a conductive material, thereby forming the conductive layers 28.

The first material layers 21 and the conductive layers 28 may be defined as a gate stack structure GST.

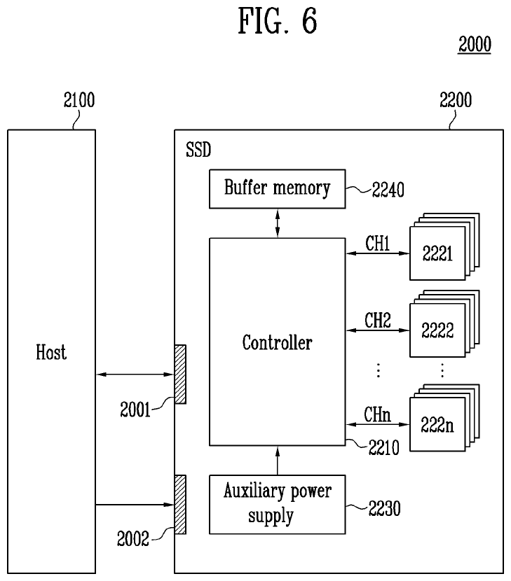

FIG. 6 is a block diagram illustrating a Solid State Drive (SSD) system to which the semiconductor device of the present disclosure is applied.

Referring to FIG. 6, the SSD system 2000 includes a host 2100 and an SSD 2200. The SSD 2200 may exchange a signal with the host 2100 through a signal connector 2001, and be supplied with power through a power connector 2002. The SSD 2200 includes a controller 2210, a plurality of memory devices 2221 to 222n, an auxiliary power supply 2230, and a buffer memory 2240.

The controller 2210 may control the plurality of memory devices 2221 to 222n in response to a signal received from the host 2100. For example, the signal may be transmitted based on an interface between the host 2100 and the SSD 2200. For example, the signal may be defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 2221 to 222n may be configured to store data, and include a plurality of nonvolatile memory cells. Each of the plurality of memory devices 2221 to 222n may be configured identically to the semiconductor device 1100 shown in FIG. 1.

The auxiliary power supply 2230 may be connected to the host 2100 through the power connector 2002. The auxiliary power supply 2230 may receive power input from the host 2100 and charge the input power. When the supply of power from the host 2100 is not smooth, the auxiliary power supply 2230 may provide power to the SSD 2200. For example, the auxiliary power supply 2230 may be located in the SSD 2200, or be located at the outside of the SSD 2200. For example, the auxiliary power supply 2230 may be located on a main board, and provide auxiliary power to the SSD 2200.

The buffer memory 2240 may be used as a buffer memory of the SSD 2200. For example, the buffer memory 2240 may temporarily store data received from the host 2100 or data received from the plurality of memory devices 2221 to 222n, or store meta data (e.g., a mapping table) of the plurality of memory devices 2221 to 222n. The buffer memory 2240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with an embodiment of the present disclosure, charge trap layers of a plurality of memory cells stacked in the vertical direction are electrically and physically spaced apart from each other, thereby reducing interference and disturb phenomena between memory cells adjacent to each other in the vertical direction.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor device comprising:
a gate stack structure including interlayer insulating layers and conductive layers, which are alternately stacked;
a channel structure extending in a vertical direction in the gate stack structure; and
memory structures interposed between the conductive layers and the channel structure,
wherein each of the memory structures includes a blocking insulating layer and a charge trap layer, which are sequentially formed on a sidewall of each of the conductive layers, and
wherein sidewalls of the interlayer insulating layers, which are in contact with the channel structure, are located on the same line as a sidewall of the charge trap layer, which is in contact with the channel structure, or side portions of the interlayer insulating layers, which are in contact with the channel structure, further protrude toward the channel structure as compared with the sidewall of the charge trap layer.

2. The semiconductor device of claim 1,
wherein the interlayer insulating layers further protrude toward the channel structure as compared with the conductive layers, and
wherein the blocking insulating layer and the charge trap layer are interposed in a space between the protruding interlayer insulating layers.

3. The semiconductor device of claim 1,
wherein the charge trap layers formed on the sidewalls of the respective conductive layers are spaced apart from each other.

4. The semiconductor device of claim 1,
wherein heights of upper surfaces of the blocking insulating layer and the charge trap layer, which correspond to any one of the conductive layers, substantially are the same.

5. The semiconductor device of claim 1,
wherein heights of lower surfaces of the blocking insulating layer and the charge trap layer, which correspond to any one of the conductive layers, are substantially the same.

6. The semiconductor device of claim 1,
wherein the channel structure includes:
a tunnel insulating layer extending in a vertical direction along the sidewalls of the interlayer insulating layers and the sidewalls of the charge trap layers; and
a channel layer extending in the vertical direction along a sidewall of the tunnel insulating layer.

7. A semiconductor device comprising:
a gate stack structure including interlayer insulating layers and conductive layers, which are alternately stacked;
a channel layer extending in a vertical direction in the gate stack structure; and
memory structures interposed between the conductive layers and the channel structure,
wherein each of the memory structures includes a blocking insulating layer, a charge trap layer, and a tunnel insulating layer, which are sequentially formed on a sidewall of each of the conductive layers, and
wherein sidewalls of the interlayer insulating layers, which are in contact with the channel structure, are located on the same line as a sidewall of the tunnel insulating layer, which is in contact with the channel structure, or side portions of the interlayer insulating layers, which are in contact with the channel structure, further protrude toward the channel structure as compared with the sidewall of the tunnel insulating layer.

8. The semiconductor device of claim 7,
wherein the interlayer insulating layers further protrude toward the channel structure as compared with the conductive layers, and
wherein the blocking insulating layer, the charge trap layer, and the tunnel insulating layer are interposed in a space between the protruding interlayer insulating layers.

9. The semiconductor device of claim 7,
wherein the charge trap layers formed on the sidewalls of the respective conductive layers are spaced apart from each other.

10. The semiconductor device of claim 7,
wherein heights of upper surfaces of the blocking insulating layer, the charge trap layer, and the tunnel insulating layer, which correspond to any one of the conductive layers, are substantially the same.

11. The semiconductor device of claim 7,
wherein heights of lower surfaces of the blocking insulating layer, the charge trap layer, and the tunnel insulating layer, which correspond to any one of the conductive layers, are substantially the same.
